(19) United States
(12) Patent Application Publication
(10) Pub. No.: US 2017/0117053 A1
(43) Pub. Date: Apr. 27, 2017

(54) SYSTEMS AND METHODS TO COMPENSATE FOR THRESHOLD VOLTAGE SHIFTS

(71) Applicant: SANDISK TECHNOLOGIES INC., Plano, TX (US)

(72) Inventors: Eran Sharon, Rishon Lezion (IL); Idan Alrod, Herzeliya (IL); Deepanshu Dutta, Fremont, CA (US)

(21) Appl. No.: 14/924,339

(22) Filed: Oct. 27, 2015

(51) Int. Cl. G11C 16/34; G06F 11/10; G11C 29/52; G11C 11/56

(52) U.S. Cl. CPC G11C 16/3404; G11C 11/5642; G11C 16/3436; G11C 11/5628; G11C 16/349; G06F 11/1068; G11C 29/52

(57) ABSTRACT

A data storage device includes a memory including multiple storage elements. The data storage device also includes circuitry configured to determine, for a particular storage element of the multiple storage elements, an indicator associated with a threshold voltage temperature dependence (TVTD) of the particular storage element.

### FIELD OF THE DISCLOSURE

The present disclosure is generally related to systems and methods to compensate for threshold voltage shifts.

### BACKGROUND

Non-volatile data storage devices, such as universal serial bus (USB) flash memory devices or removable storage cards, have allowed for increased portability of data and software applications. Flash memory devices can enhance data storage density by storing multiple bits in each flash memory cell. For example, Multi-Level Cell (MLC) flash memory devices provide increased storage density by storing 3 bits per cell, 4 bits per cell, or more.

A threshold voltage (Vt) of a MLC flash memory cell may be programmed to a particular state of one or more states. Each state of the one or more states corresponds to a threshold voltage range. Cells programmed to the same bit value are programmed with threshold voltages within the same threshold voltage range. Thus, a logical value of a memory cell may be determined based on the voltage range in which the cell's threshold voltage lies. Each threshold voltage range is bounded by an upper and lower bound read reference voltage. During operation, the cell's threshold voltage may be iteratively compared to predefined read reference voltages until the upper and lower bound read reference voltages are identified, thus determining the threshold voltage range within which the cell's threshold voltage lies.

A flash memory cell may exhibit a threshold voltage shift due to a change in temperature between a temperature at which the cell was programmed and a temperature at which the cell is read. Thus, the upper and lower bounds of a threshold voltage range may shift due to a temperature change between a time of programming of a memory cell and a subsequent time of reading the memory cell. Cells in a flash memory may exhibit different amounts of threshold voltage shift due to temperature changes. For example, a first memory cell programmed with a threshold voltage within a first threshold voltage range at a first temperature may experience a smaller threshold voltage shift when read at a second temperature than a second memory cell programmed with a threshold voltage within the first threshold voltage range. The different threshold voltage shifts experienced by different cells programmed with a threshold voltage within the same threshold voltage range may cause the threshold voltage ranges to widen, making it difficult to distinguish between states of the memory cells and therefore increasing a bit error rate (BER) of the memory cells.

### BRIEF DESCRIPTION OF THE DRAWINGS

FIG. 1 is a block diagram of a particular illustrative embodiment of a system including a data storage device configured to compensate for threshold voltage shifts.

FIG. 2 is a general diagram that illustrates examples of threshold voltage distribution shifts.

FIG. 3 is a block diagram illustrating a particular embodiment of components that may be incorporated in the data storage device of FIG. 1.

FIG. 4 is a block diagram illustrating another embodiment of components that may be incorporated in the data storage device of FIG. 1.

FIG. 5 is a flow chart of a particular illustrative embodiment of a method of compensating for threshold voltage shifts.

### DETAILED DESCRIPTION

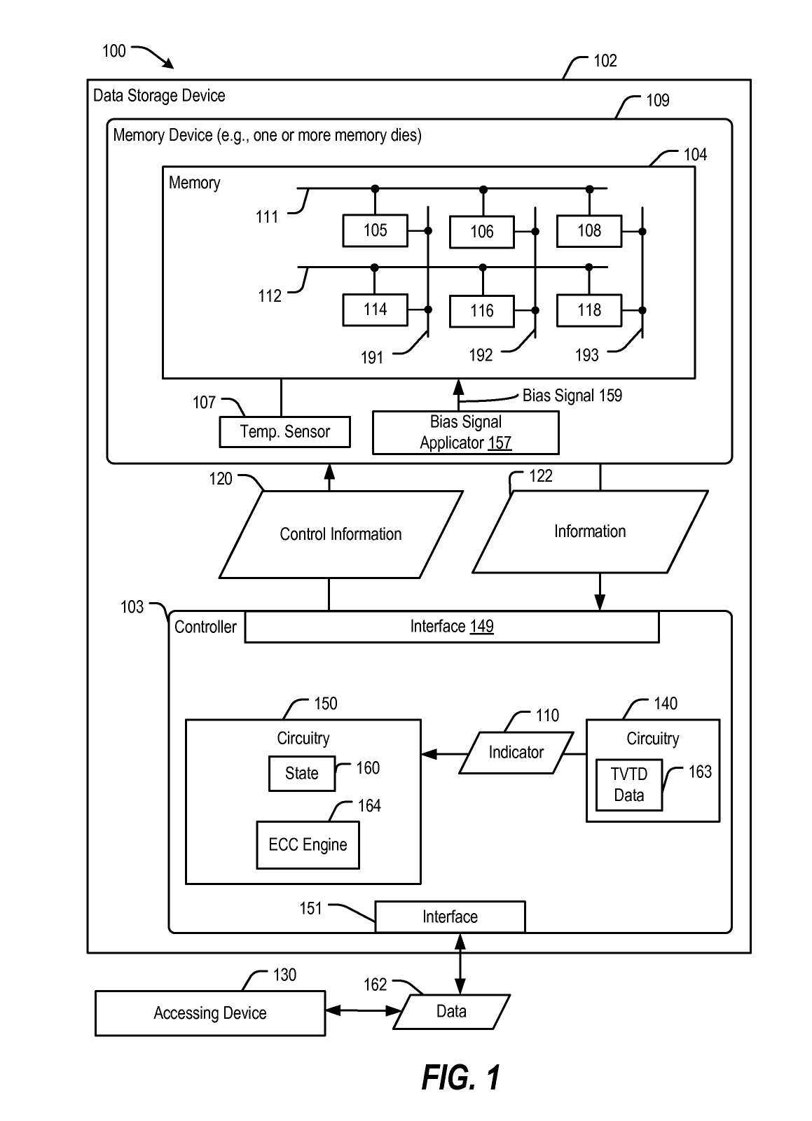

Referring to FIG. 1, a particular embodiment of a system 100 includes a data storage device 102 coupled to an accessing device 130 (e.g., a host). The data storage device 102 may be configured to determine an indicator 110 associated with a threshold voltage temperature dependence (TVTD).

The data storage device 102 includes a memory device 109 that includes a memory 104 (e.g., a non-volatile memory (NVM)). The memory 104 may correspond to or may include any type of non-volatile memory, such as a flash memory (e.g., NAND flash memory). The memory 104 may include multiple storage elements, such as storage elements 105, 106, and 108 coupled to a first word line 111 and storage elements 114, 116, and 118 coupled to a second word line 112. The storage elements 105 and 114 are coupled to a first bit line 191, the storage elements 106 and 116 are coupled to a second bit line 192, and the storage elements 108 and 118 are coupled to a third bit line 193. Each of the storage elements 105, 106, 108, 114, 116, and 118 may correspond to or may include a memory cell (e.g., a NAND flash memory cell). During operation, the accessing device 130 may provide data 162 to the data storage device 102.

The data storage device 102 includes a controller 103 coupled to the memory device 109 (e.g., via an interface 149). The controller 103 may be configured to receive the data 162 from the accessing device 130 (e.g., via an interface 151) and to send data and/or commands, such as control information 120, to the memory 104. The controller 103 may be configured to receive information, such as information 122 that may include read values read from one or more of the storage elements 105, 106, 108, 114, 116, and 118; one or more representations of one or more codewords read from storage elements including one or more of the storage elements 105, 106, 108, 114, 116, and 118; and/or temperature information from a temperature sensor 107.

The temperature sensor 107 may be configured to measure a temperature corresponding to one or more of the storage elements 105, 106, 108, 114, 116, and/or 118. A change in temperature between a time of programming a storage element and a time of reading the storage element may be referred to as a “temperature cross.” In some examples, the data storage device 102 may be configured to store, at the controller 103, temperature information associated with a temperature at a time of programming the memory 104. For example, the data storage device 102 may be configured to store, at the controller 103 or at the memory 104, a “time tag” that indicates information including a temperature at a time of programming a block of the memory 104. Alternatively or additionally, the data storage device 102 may be configured to store, at the memory 104, one or more flag bits indicative of a temperature at a time of programming the memory 104. For example, each word line of the memory 104 may include a flag bit indicative of a temperature at a time of programming the word line.

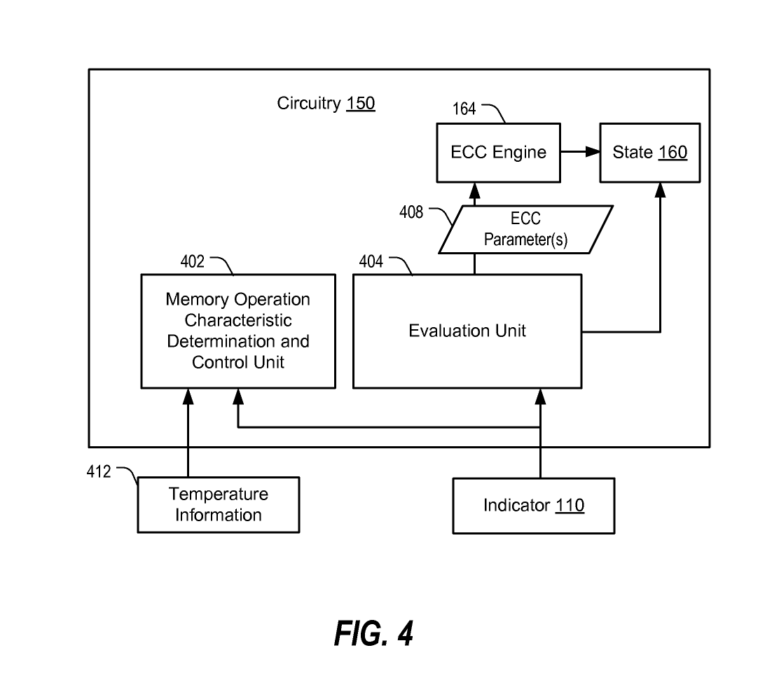

The controller 103 includes circuitry 140. The circuitry 140 may be configured to determine an indicator 110 for one or more storage elements of the multiple storage elements 105, 106, 108, 114, 116, and 118. The value of the indicator 110 of a storage element may be associated with a TVTD (e.g., a “temperature coefficient” (Tco)) of the particular storage element. For example, the value of the indicator 110 of a storage element may be determined based on TVTD data 163 (e.g., Tco data) of the storage element, as described in more detail below. The controller 103 also include circuitry 150 that is configured to determine a state 160 of a storage element at least partially based on output of an ECC engine 164, such as described in further detail with respect to FIG. 4.

The TVTD of a storage element may be a value, parameter, or function indicative of an amount or rate of threshold voltage shift that a storage element is prone to experience at least in part as a result of a temperature cross. Equation 1 and Equation 2 provide examples of a TVTD of a particular storage element i (TVTDⁱ), where “i” identifies the particular storage element, ‘∂’ indicates a partial derivative, ‘Vₜⁱ’ corresponds to a threshold voltage of the particular storage element i, and ‘T’ corresponds to a temperature (e.g., of the memory 104 or the particular storage element i).

$$\begin{matrix}{TVTD}^{i} = \frac{\partial {V}_{t}^{i}}{\partial T} & ( Eq . 1 ) \\ {TVTD}^{i} = \frac{1}{{V}_{t}} \times \frac{\partial {V}_{t}^{i}}{\partial T} & ( Eq . 2 )\end{matrix}$$

The TVTD of a storage element i (TVTDⁱ) may be positive or negative. A negative TVTDⁱ may indicate that the threshold voltage is inversely related to temperature.

The TVTD data 163 of a storage element may be any data related to, correlated with, or useful to characterize or categorize a storage element based on the TVTD of the storage element. In some examples, the TVTD data 163 of the particular storage element may be determined independent of temperature of the storage element by computing a characteristic that is indicative of the TVTD of the particular storage element and independent of temperature information. To illustrate, a drain induced barrier lowering (DIBL) of the particular storage element may be indicative of an extent of threshold voltage shift that a storage element is prone to experience at least in part as a result of a temperature cross (e.g., may be correlated with the TVTD of Equations 1 or 2 above). In these examples, the TVTD data 163 of a storage element may correspond to or be associated with a determined DIBL of the particular storage element. In some examples, the data storage device 102 may be configured to determine a DIBL (e.g., the TVTD data 163) for storage elements of a word line by performing reads of the word line with different bit line voltages and computing a difference between read threshold voltages.

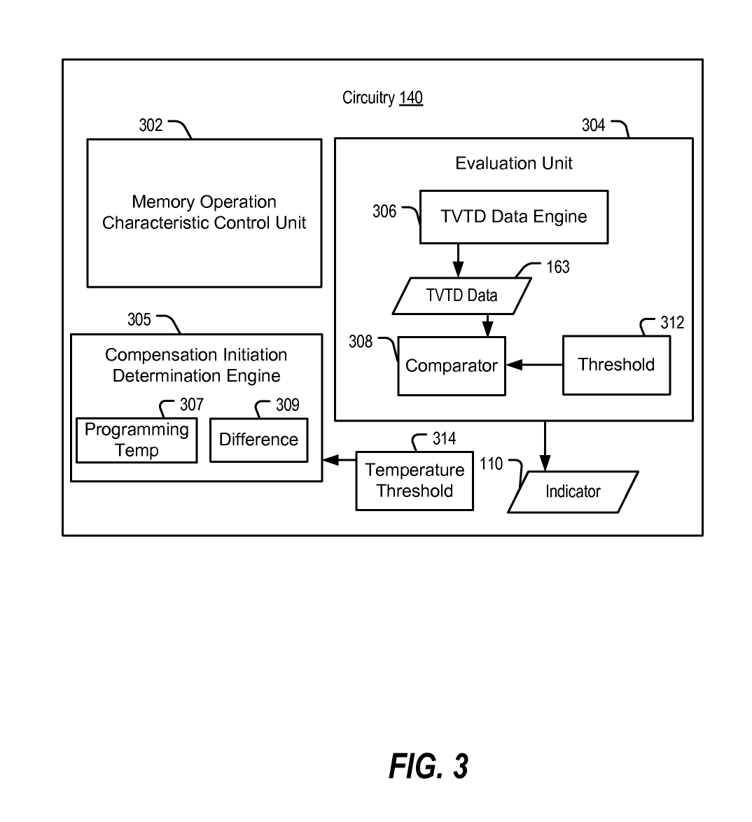

For example, FIG. 3 illustrates an example of the circuitry 140 of FIG. 1. In this example, a memory operation characteristic control unit 302 may cause the memory 104 to perform reads of one or more storage elements using particular bit line voltages. For example, the memory operation characteristic control unit 302 may instruct the memory 104 to perform a first read of the word line 111 while applying a first bit line voltage (e.g., 0.5V) to one or more of the bits lines 191-193 of the storage elements 105, 106, and/or 108 of the word line 111 to determine a first threshold voltage (e.g., a “first Vt” threshold voltage range) for each of the one or more storage elements 105, 106, and 108. The memory operation characteristic control unit 302 may instruct the memory 104 to perform a second read of the word line 111 while applying a second bit line voltage (e.g., 0.75V) to one or more of the bit lines 191-193 of the storage elements 105, 106, and/or 108 of the word line 111 to determine a second threshold voltage (e.g., a “second Vt” threshold voltage range) for each of the one or more storage elements 105, 106, and 108.

The first and second threshold voltages may be provided to the controller 103. For example, the first Vt and the second Vt may be provided to an evaluation unit 304 of FIG. 3. The evaluation unit 304 may include a TVTD data engine 306. For each of the one or more storage elements 105, 106, and/or 108, the TVTD data engine 306 may be configured to determine a difference between the first Vt of the storage element and the second Vt of the storage element. The difference determined for the storage element may correspond to the DIBL of the storage element. Alternatively, the DIBL of a storage element may correspond to the determined difference between the first Vt and the second Vt of the storage element divided by an amount corresponding to a difference between the first bit line voltage and the second bit line voltage. For example, the circuitry 140 may determine the difference (“Vₓ”) between the first Vt of the storage element 105 and the second Vt of the storage element 105, and the TVTD data engine 306 may determine that the DIBL for the storage element 105 corresponds to Vx divided by the difference between the first bit line voltage and the second bit line voltage.

The data storage device 102 (e.g., the circuitry 140) may be configured to determine the indicator 110 for a storage element based on whether the TVTD data 163 of the storage element (e.g., the DIBL of the storage element) satisfies a threshold (e.g., equals or exceeds the threshold 312 of FIG. 3). The threshold 312 may correspond to a value of the TVTD data 163 that is indicative of a “substantially high” TVTD (e.g., a TVTD that is greater than one standard distribution above a mean TVTD value). In some examples, the indicator 110 may be a single bit. For example, the circuitry 140 may assign a first logical value (e.g., 1) to storage elements for which the TVTD data 163 does not satisfy the threshold 312 (e.g., when the TVTD is not substantially high), and may assign a second logical value (e.g., 0) to storage elements for which the TVTD data 163 does satisfy the threshold 312 (e.g., when the TVTD is substantially high).

To illustrate, the circuitry 140 may include a comparator 308 of FIG. 3 configured to compare the TVTD data 163 of a storage element (e.g., the storage element 105) to the threshold 312 to determine whether the TVTD data 163 of the storage element 105 satisfies the threshold 312. The evaluation unit 304 may assign the storage element 105 a first value of the indicator 110 when the comparator 308 determines that the TVTD data 163 of the storage element 105 does not satisfy the threshold 312 and may assign the storage element 105 a second value of the indicator 110 when the comparator 308 determines that the TVTD data 163 of the storage element 105 satisfies the threshold 312. The first value of the indicator 110 may be indicative of storage elements that have a relatively low TVTD, and the second value of the indicator 110 may be indicative of storage elements that have a relatively high TVTD.

Thus, the circuitry 140 may determine a value of the indicator 110 for each of one or more of the storage elements 105, 106, 108, 114, 116, and/or 118 based on TVTD data of the storage element, and the value of the indicator 110 of a storage element may be indicative of how sensitive a threshold voltage of the storage element is to threshold voltage shift due to a change in temperature (e.g., due to a temperature cross). The data storage device 102 may use the value of the indicator 110 of a storage element to determine a state of the storage element, as described in more detail below.

In some examples, the circuitry 140 may be configured to determine the TVTD data 163 and a value of the indicator 110 for each storage element of the multiple storage elements 105, 106, 108, 114, 116, and 118 during an operation (e.g., a memory operation) performed on the storage element or in response to an instruction or command to perform the operation on the storage element. For example, the memory operation may correspond to a read operation, a program verify operation, or a cell voltage distribution (CVD) determination operation. For example, a memory operation may be performed on the word line 111 (e.g., on one or more storage elements of the word line 111) and the circuitry 140 may determine the TVTD data 163 for each of the storage elements 105, 106, and 108 as part of the operation. The circuitry 140 may determine a value of the indicator 110 for each of the storage elements 105, 106, and 108 as part of the operation based on the TVTD data 163 determined for the storage element as described below. Thus, the circuitry 140 may determine a value of the indicator 110 for each storage element based on TVTD data 163 specific to the storage element. Determining the indicator 110 for a storage element based on TVTD data specific to the storage element may enable the data storage device 102 to account for non-uniform threshold voltage shifts among storage elements (that result in state widening) as compared to systems that employ a uniform temperature coefficient for the storage elements. Additionally, determining the values of the indicator 110 (and the TVTD data 163) for storage elements when the storage elements are operated on may enable the data storage device 102 to avoid storing the TVTD data or associated indicators in memory.

In some examples, the data storage device 102 may be configured to conditionally perform compensation operations that include determining the TVTD data 163 and the indicator 110 for a storage element responsive to temperature information (e.g., from the temperature sensor 107) associated with the storage element. For example, the data storage device 102 may be configured to conditionally perform the compensation operations responsive to a temperature associated with the storage element satisfying a threshold. The threshold may be indicative of a programming temperature at which the storage element is likely to experience a temperature cross that may result in distribution widening. The TVTD data 163 and the indicator 110 may be determined by the circuitry 140 as described with respect to FIG. 3 and may be used by the circuitry 150 (e.g., to digitally adjust data based on the TVTD data 163 or the indicator 110) as described with respect to FIG. 4.

To illustrate, the controller 103 may determine to perform a first memory operation (e.g., a read operation or a program verify operation) at the memory 104 of FIG. 1 (e.g., at the word line 111). The circuitry 140 (e.g., a compensation initiation determination engine 305 of FIG. 3) may access temperature information (e.g., the time tag from the controller 103 or the flag bit from the memory 104 of FIG. 1) to determine whether a temperature at the time of programming the word line 111 (e.g., a programming temperature 307) satisfies a temperature threshold 314 of FIG. 3 (e.g., a programming temperature threshold) that may be indicative of a programming temperature at which one or more of the storage elements 105, 106, and/or 108 of the word line 111 of FIG. 1 are likely to experience a temperature cross that may result in distribution widening. When the compensation initiation determination engine 305 determines that the programming temperature 307 satisfies the temperature threshold 314, the controller 103 may initiate the compensation operations to determine the TVTD data 163 and the indicator 110. When the compensation initiation determination engine 305 determines that the programming temperature 307 does not satisfy the temperature threshold 314, the controller 103 may not initiate the compensation operations (e.g., may cause the memory 104 to perform the first memory operation without the data storage device 102 determining the TVTD data 163 and the indicator 110).

To illustrate, the compensation initiation determination engine 305 may be configured to compare the programming temperature 307 to the temperature threshold 314 to determine whether the programming temperature 307 satisfies (e.g., equals or exceeds) the temperature threshold 314. When the compensation initiation determination engine 305 determines that the programming temperature 307 satisfies the temperature threshold 314, the circuitry 140 may proceed with determining the TVTD data 163 and the indicator 110 for one or more of the storage elements 105, 106, and/or 108 of the word line 111 of FIG. 1. For example, the compensation initiation determination engine 305 may issue a command that instructs the memory operation characteristic control unit 302 to issue a command to the memory 104 of FIG. 1 that causes the memory 104 to perform one or more second operations, such as high resolution reads using different bit line voltages to determine a DIBL as described in more detail below, to generate information that the evaluation unit 304 may use to determine the TVTD data 163. When the compensation initiation determination engine 305 of FIG. 3 determines that the programming temperature 307 does not satisfy the temperature threshold 314, the circuitry 140 may not determine the TVTD data 163 and the indicator 110 for the storage elements of the word line 111, and the controller 103 may instruct the memory 104 to perform the first operation (e.g., a read operation) without performing the one or more second operations.

Alternatively or additionally, in some examples, the data storage device 102 may be configured to conditionally perform the compensation operations responsive to (e.g., only when) a difference 309 between a first temperature of the memory 104 or one or more particular storage elements of the multiple storage elements 105, 106, 108, 114, 116, and/or 118 at a time of programming the particular storage element and a second temperature of the memory 104 or one or more of the storage elements of the multiple storage elements 105, 106, 108, 114, 116, and/or 118 satisfies a threshold, such as the temperature threshold 314. The threshold (e.g., a temperature difference threshold) may be indicative of a temperature cross that may, or is likely to, result in problematic state widening.

For example, the controller 103 may determine to perform a first operation (e.g., a read operation or a program verify operation) at the memory 104 of FIG. 1 (e.g., at the word line 111). The compensation initiation determination engine 305 of FIG. 3 may access temperature information (e.g., the time tag from the controller 103 or the flag bit from the memory 104 of FIG. 1) to determine whether the difference 309 between the programming temperature 307 and a read temperature is likely to or may result in problematic distribution widening. When the compensation initiation determination engine 305 determines that the difference 309 satisfies the temperature threshold 314, the controller 103 may initiate the compensation operations to determine the TVTD data 163 and the indicator 110. When the compensation initiation determination engine 305 determines that the difference 309 does not satisfy the temperature threshold 314, the controller 103 may not initiate the compensation operations (e.g., may cause the memory 104 to perform the first operations without the data storage device 102 determining the TVTD data 163 and the indicator 110).

Thus, the data storage device 102 of FIG. 1 may conditionally perform compensation operations (e.g., may conditionally determine the TVTD data 163 and/or the indicator 110) during an operation responsive to temperature information indicative of a temperature cross that is likely to cause one or more storage elements to experience a threshold voltage shift or state widening.

As described in more detail below, the data storage device 102 may perform one or more memory operations on a storage element based on a TVTD of the storage element (e.g., to compensate for threshold voltage shift or state widening). The one or more memory operations may include a read operation, a program verify operation, and/or a distribution read operation. In some examples, the data storage device 102 may perform a first memory operation on a first storage element (e.g., the storage element 105) using a memory operation characteristic (e.g., a “first characteristic”) based on a first TVTD of the first storage element 105. Alternatively or additionally, the data storage device 102 may perform a second memory operation on a second storage element (e.g., the storage element 106) using a memory operation characteristic (e.g., a “second characteristic”) based on a second TVTD of the second storage element 106. The first TVTD of the first storage element 105 may be different than the second TVTD of the second storage element 106. In some examples, the second characteristic may be different than the first characteristic (e.g., due to the first TVTD being different than the second TVTD). In some examples, the first memory operation and/or the second memory operation may include determining a state of a storage element based on a value of the indicator 110 of the storage element. In these examples, the characteristic (e.g., the first and/or second characteristics) of the storage elements may be determined based on the TVTD of the storage element as indicated by a value of the indicator 110 of the storage element.

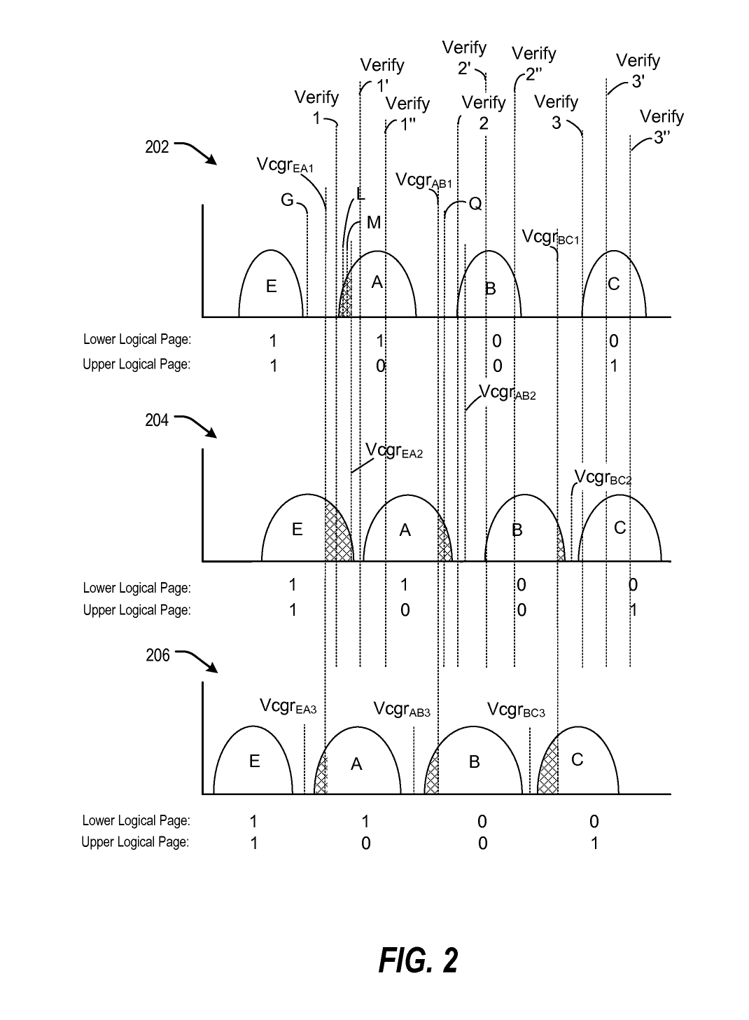

Distribution plots 202, 204, and 206 of FIG. 2 may be used to illustrate aspects of threshold voltage shift, state widening, and/or compensation techniques based on a TVTD of a storage element. The distribution plot 202 may correspond to a threshold voltage distribution plot of the storage elements of the word line 111 of FIG. 1 as programmed at a first temperature. Each distribution plot 202, 204, and 206 includes four lobes that represent storage element states (states “E”, “A”, “B”, and “C”). Each state corresponds to a 2-bit value. For example, storage elements set to state E may store the 2-bit value ‘11’, storage elements set to state A may store the value ‘10’, storage elements in state B may store the value ‘00’, and storage elements set to state C may store the value ‘01’. Voltages Vcgr_{EA1}, Vcgr_{AB1}, and Vcgr_{BC1} illustrated in the distribution plot 202 of FIG. 2 may correspond to first read compare voltages associated with programming the storage elements 105, 106, and 108 of FIG. 1 at the first temperature (e.g., may correspond to unadjusted read compare voltages). Alternatively, the first read compare voltages VcgrEA1, Vcgr_{AB1}, and Vcgr_{BC1} may correspond to adjusted read compare voltages that are adjusted using less of an offset than second read compare voltages.

Each of the distribution plots 204 and 206 of FIG. 2 may correspond to threshold voltage distribution plots of the storage elements 105, 106, and 108 of the word line 111 of FIG. 1 at different temperatures than the first temperature (e.g., at a second temperature). For example, the distribution plot 204 may illustrate a threshold voltage distribution of the storage elements 105, 106, and 108 at a second temperature that is less than the first temperature (e.g., a positive temperature cross), resulting in a positive voltage shift. For example, Vcgr_{EA2}, Vcgr_{AB2}, and Vcgr_{BC2} illustrated in the distribution plot 204 of FIG. 2 may correspond to “optimal” read compare voltages associated with reading the storage elements 105, 106, and 108 of FIG. 1 at the second temperature (e.g., the “optimal” read compare voltages may be at mid-points between the lobes of the distribution plots). As indicated in the distribution plot 204 of FIG. 2, states of the distribution plot 202 have shifted “up” (to higher voltages) and widened, resulting in the read compare voltages associated with programming at the first temperature being located within distribution lobes associated with reading at the second temperature (e.g., VcgrEA1 is within state E of distribution plot 204). Thus, performing a read operation (e.g., reading the states of the storage elements 105, 106, and/or 108) at the second temperature using the read compare voltages associated with programming the storage elements 105, 106, and/or 108 at the first temperature may result in storage elements having a threshold voltage level within the cross-hatched portion of the states of plot 204 to be incorrectly read as storing a different state than the state to which the storage element was programmed.

The distribution plot 206 of FIG. 2 may correspond to a threshold voltage distribution of the storage elements 105, 106, and 108 of the word line 111 of FIG. 1 at a third temperature. In some examples, the third temperature may be greater than the first temperature (e.g., a negative temperature cross), resulting in a negative voltage shift. For example, Vcgr_{EA3}, Vcgr_{AB3}, and Vcgr_{BC3} illustrated in the distribution plot 206 of FIG. 2 may correspond to “optimal” read compare voltages associated with reading the storage elements 105, 106, and 108 of FIG. 1 at the third temperature. As indicated in the distribution plot 206 of FIG. 2, the states of the distribution plot 202 (e.g., distribution plot at the first temperature) have shifted “down” (to lower voltages) and widened, resulting in the read compare voltages associated with programming at the first temperature to fall within lobes associated with reading at the third temperature (e.g., Vcgr_{EA1} is within state A of distribution plot 206). Thus, reading the states at the third temperature using the read compare voltages associated with programming at the first temperature would result in storage elements in the cross-hatched portion of the states of the distribution plot 206 to be incorrectly read as storing a different state.

In some examples, the one or more memory operations may include one or more read operations. In these examples, to compensate for the shifting and widening (e.g., due to varying threshold voltage temperature dependence of a storage element) of states during a read operation at the memory 104, the data storage device 102 may be configured to perform the one or more read operations having one or more characteristics based on a TVTD of the storage element, as described in more detail below. For example, the one or more characteristics of the one or more read operations may include a read compare voltage, a VREAD voltage, a bit line voltage, and/or a reliability metric, as described in more detail below.

In some examples, the one or more characteristics of the one or more read operations may include one or more read compare voltages of a read operation. In these examples, to compensate for the shifting and widening (e.g., due to varying threshold voltage temperature dependence of a storage element) of states during a read operation at the memory 104, the data storage device 102 may be configured to perform one or more read operations using one or more read compare voltages determined based on a TVTD of the storage element. For example, the data storage device 102 may read a storage element using a first read operation having one or more first read compare voltages including a first read compare voltage when the TVTD of the storage element is relatively low (e.g., when a value of the indicator 110 of the storage element being read has a first value indicative of a relatively low TVTD). Alternatively or additionally, the data storage device 102 may read the storage element using a second read operation having one or more second read compare voltages including a second read compare voltage when the TVTD of the storage element is relatively high (e.g., when a value of the indicator 110 of the storage element being read has a second value indicative of a relatively high TVTD).

The one or more first read compare voltages including the first read compare voltage may correspond to one or more read compare voltages within state margins of a charge voltage distribution of the memory 104 at a reference temperature (e.g., a temperature at a time of programming at least a portion of the memory 104). To illustrate, the first read operation may employ one or more first read compare voltages Vcgr_{EA1}, Vcgr_{AB1}, and Vcgr_{BC1} including a first read compare voltage (e.g., Vcgr_{AB1}). The one or more first read compare voltages may be suitable to read a storage element that is programmed and read at a nominal temperature (e.g., or at zero temperature cross) and/or may be suitable to read a storage element at a temperature cross when the storage element has a relatively low TVTD. The one or more second read compare voltages including the second read compare voltage may be selected to compensate for larger voltage shifts of storage elements that are prone to relatively large voltage shifts in response to temperature cross. For example, the second read operation may employ one or more second read compare voltages Vcgr_{EA2}, Vcgr_{AB2}, and Vcgr_{BC2} including a second read compare voltage (e.g., Vcgr_{AB2}).

In some examples, the one or more first read compare voltages of the first read operation and/or the one or more second read compare voltages of the second read operation may be determined by the data storage device 102 based at least in part on temperature information (e.g., from the time tag and/or temperature flag and the temperature sensor 107). In some examples, the one or more read compare voltages may be determined as a function of a temperature difference between the programming temperature and the reading temperature. For example, the second read compare voltage Vcgr_{AB2} of the second read operation may be determined as in Equation 3, where T̅co corresponds to an average temperature coefficient determined for the memory 104, T₁ corresponds to a temperature at a time of programming (a storage element), and T₂ corresponds to a temperature at a time of reading (the storage element).

Vcgr_{AB2}=Vcgr_{AB1}×(1+T̅co(T₁−T₂)) (Eq. 3)

For example, as depicted in FIG. 4, the circuitry 150 may include a memory operation parameter determination and control unit 402 that is configured to access temperature information 412 to determine T₁ and T₂. For example, the memory operation parameter determination and control unit 402 may access the time tag from the controller 103 or the flag bit from the memory 104 of FIG. 1 (described above) to determine T₁ and may access temperature information from the temperature sensor 107 to determine T₂. The memory operation characteristic determination and control unit 402 may determine the second read compare voltage Vcgr_{AB2} as described in Equation 3 based on the determined T₁ and T₂ (e.g., the determined temperature cross).

In some examples, the one or more first read compare voltages (of the first read operation) may correspond to original, initial, or unadjusted read compare voltages, and the one or more second read compare voltages (e.g., of the second read operation) may correspond to adjusted read compare voltages. Thus, the data storage device 102 may be configured to read (e.g., at a temperature cross) storage elements that have a relatively low TVTD (e.g., storage elements that have a value (e.g., the first value) of the indicator 110 indicative of a relatively low TVTD) using a read operation (e.g., the first read operation) that employs unadjusted read compare voltages, and may be configured to read (e.g., at the temperature cross) storage elements that have a relatively high TVTD (e.g., storage elements that have a value (e.g., the second value) of the indicator 110 indicative of a relatively high TVTD) using a read operation (e.g., the second read operation) that employs adjusted, modified, or compensated read compare voltages.

Reading one or more of the storage elements by selectively using the first read operation having the one or more first read compare voltages or the second read operation having the one or more second read compare voltages based on the TVTD of the storage elements (e.g., based on a value of the indicator 110 of the storage element) may enable the data storage device 102 to compensate for threshold voltage shifts in a manner that accounts for variations in shifts experienced by storage elements in response to the same temperature cross.

For example, the storage element 105 may have a relatively low TVTD (e.g., may have a value (e.g., the first value) for the indicator 110 corresponding to a relatively low TVTD). In this example, the circuitry 150 may be configured to read the storage element 105 (e.g., to determine the state 160 of the storage element 105) by performing the first read operation having the one or more first read compare voltages by applying, and/or by causing or instructing the memory 104 to apply, the one or more first read compare voltages to the word line 111 based on the storage element 105 having a relatively low TVTD (e.g., having a value (e.g., the first value) of the indicator 110 of the storage element 105 indicating a relatively low TVTD). Reading the storage element 105 by performing the first read operation having the one or more first read compare voltages, as opposed to reading the storage element 105 based on the second read operation (e.g., having the one or more second read compare voltages), when the storage element 105 has a relatively low TVTD (e.g., when the indicator 110 for the storage element 105 has the first value) may result in a correct state determination.

To illustrate, the storage element 105 may have a relatively low TVTD (e.g., may have the first value of the indicator 110), and may be programmed to store data associated with state A of the distribution plot 202. For example, the storage element 105 may be programmed to a threshold voltage corresponding to L as in the distribution plot 202 at a first temperature. In this example, the storage element 105 may have a threshold voltage corresponding to M at a second temperature (e.g., the threshold voltage of the storage element 105 may experience a shift to M at the second temperature due to the temperature cross). In this example, the circuitry 150 of FIG. 1 (e.g., the memory operation parameter determination and control unit 402) may perform the first read operation by applying, and/or by issuing a command to cause the memory 104 to apply, the one or more first read compare voltages including the first read compare voltage (Vcgr_{AB1}) as in the distribution plot 202 of FIG. 2 based on the storage element 105 having a relatively low TVTD (e.g., based on the indicator 110 for the storage element 105 having the first value). Because the threshold voltage of the storage element 105 is at voltage M at the second temperature, the storage element 105 may be conductive in response to the first read compare voltage Vcgr_{AB1}, indicative of state A, when the storage element 105 is read at the second temperature using the first read operation (e.g., using the one or more first read compare voltages). The memory 104 may measure a first read value of the storage element 105 indicative of state A in response to the first read compare voltage Vcgr_{AB1} and may provide the first read value to the circuitry 150. The circuitry 150 may determine that the state 160 of the storage element 105 corresponds to state A based on the first read value indicating state A.

In some examples, the first read compare voltages may correspond to default read compare voltages that are not adjusted for temperature, and the second read compare voltages are adjusted for temperature to compensate for storage elements having relatively high TVTD. In other examples, the first read compare voltages may correspond to read compare voltages that are adjusted for temperature (to compensate for storage elements having relatively low TVTD) but have a lesser adjustment amount as compared to the second read compare voltages (that are adjusted to compensate for storage elements having relatively high TVTD). Thus, the data storage device 102 may correctly determine a state of the storage element 105 at the temperature cross using the first read operation having the one or more first read compare voltages, and the first read compare voltages may correspond to adjusted read compare voltages (using less of an offset than the second read compare voltages) or unadjusted read compare voltages.

In this example, if the second read operation was used to read the storage element 105, the storage element 105 may have become conductive in response to application of a read compare voltage (of the one or more second read compare voltages of the second read operation) that is associated with a state other than state A. For example, the storage element 105 may have become conductive in response to the read compare voltage Vcgr_{EA2} associated with state E, thereby resulting in an incorrect read result (e.g., a read result or state estimate indicative of state E as opposed to state A) if the second read operation was used to read the storage element 105 at the temperature cross. Thus, by determining, at the temperature cross, the read value of the storage element 105 having a relatively low TVTD (e.g., having the first value of the indicator 110 for the storage element 105) using the first read operation having the one or more first read compare voltages including the first read compare voltage as opposed to the second read operation, the circuitry 150 may correctly determine a state (e.g., A) of the storage element 105 despite a threshold voltage shift due to the temperature cross.

As another example, the storage element 106 may have a relatively high TVTD (e.g., the indicator 110 for the storage element 106 may have the second value). In this example, the circuitry 150 may be configured to read the storage element 106 (e.g., to determine the state 160 of the storage element 106) by performing the second read operation having the one or more second read compare voltages by applying, and/or by causing or instructing the memory 104 to apply, the one or more second read compare voltages to the word line 111 based on the storage element 106 having a relatively high TVTD (e.g., based on the indicator 110 for the storage element 106 having the second value). Reading the storage element 106 at the temperature cross by performing the second read operation having the one or more second read compare voltages, as opposed to reading the storage element 106 at the temperature cross using the first read operation having the one or more first read compare voltages when the storage element 106 has a relatively high TVTD (e.g., when the indicator 110 for the storage element 106 has the second value) may result in a correct state determination for the storage element 106 despite being subjected to the same temperature cross as the storage element 105.

To illustrate, the storage element 106 may have a relatively high TVTD (e.g., may have the second value of the indicator 110), and may be programmed to store data associated with state A of distribution plot 202. For example, the storage element 106 may be programmed to a threshold voltage corresponding to L as in the distribution plot 202 at a first temperature. In this example, the storage element 106 may have a threshold voltage corresponding to Q at the second temperature (e.g., the threshold voltage of the storage element 106 may shift to Q at the second temperature due to the temperature cross). Thus, due to different characteristics of the storage elements (e.g., such as short channel effects), the threshold voltage of the storage element 106 may experience a larger voltage shift than the storage element 105 due to the temperature change from the first temperature (at the time of programming) to the second temperature (e.g., due to the temperature cross). Because Q represents a threshold voltage larger than Vcgr_{AB1}, the storage element 106 would be incorrectly read as being in state B using the read compare voltages of distribution plot 202.

In this example, the circuitry 150 of FIG. 1 (e.g., the memory operation parameter determination and control unit 402) may read the storage element 106 by performing the second read operation by applying, and/or by issuing a command or instruction to cause the memory 104 to apply, the one or more second read compare voltages based on the storage element 106 having a relatively high TVTD (e.g., based on the indicator 110 of FIG. 1 for the storage element 106 having the second value). Because the threshold voltage of the storage element 106 is at voltage Q at the second temperature, the storage element 106 may become conductive in response to the second read compare voltage Vcgr_{AB2} indicative of state A when the storage element 106 is read at the second temperature using the second read operation (e.g., the one or more second read compare voltages). The memory 104 may measure a second read value of the storage element 106 indicative of state A in response to the second read compare voltage Vcgr_{AB2} and may provide the second read value to the circuitry 150. The circuitry 150 may determine the state 160 of the storage element 106 to correspond to state A based on the second read value indicating state A. Thus, the circuitry 150 may correctly determine a state of the storage element 106 at the temperature cross using the second read operation having the one or more second read compare voltages.

Thus, the data storage device 102 may read a storage element using a characteristic (e.g., a read compare voltage) based on a TVTD of the storage element (e.g., based on a value of the indicator 110 for the storage element), and reading the storage element having the characteristic based on the TVTD of the storage element may enable the data storage device 102 to compensate for threshold voltage shifts in a manner that accounts for variations in shifts experienced by storage elements in response to the same temperature cross.

In some examples, the data storage device 102 may be configured to read one or more storage elements (e.g., of a word line) by performing multiple read operations (e.g. the first read operation and the second read operation) having different read compare voltages and selecting a read result (e.g., a state estimate) of a particular read operation for a storage element based on the TVTD of the storage element (e.g., based on a value of the indicator 110 of the storage element). For example, the circuitry 150 or circuitry on the memory 104 may perform the first read operation (e.g., may apply the one or more first read compare voltages) and the second read operation (e.g., may apply the one more second read compare voltages) to the word line 111 and may select a read result (e.g., a state estimate) of a particular read operation for the storage elements 105 and/or 106 based the TVTD of the storage elements 105 and/or 106 (e.g., based on a value of the indicator 110 of the storage element 105 and/or 106).

To illustrate, the storage elements 105 and 106 may be programmed to threshold voltage L at the first temperature as described above, and may have respective threshold voltages M and Q at the second temperature (e.g., as a result of the temperature cross) as described above. The storage element 105 may have a relatively low TVTD (e.g., the indicator 110 for the storage element 105 may have the first value), the storage element 106 may have a relatively high TVTD (e.g., the indicator 110 for the storage element 106 may have the second value), and the data storage device 102 may be configured to read the word line 111 (including the storage elements 105 and 106) at the second temperature.

To read the word line 111 at the second temperature, the circuitry 150 may issue one or more commands to the memory 104 to cause the memory 104 to perform the first read operation at the word line 111 by applying the one or more first read compare voltages Vcgr_{EA1}, Vcgr_{AB1}, and Vcgr_{BC1} to read the storage element 105 at state A (e.g., a first read result or state estimate of the storage element 105) and the storage element 106 at state B (e.g., a first read result or state estimate of the storage element 106). The one or more commands may additionally cause the memory 104 to perform the second read operation at the word line 111 by applying the second read compare voltages Vcgr_{EA2}, Vcgr_{AB2}, and Vcgr_{BC2} to read storage element 105 at state E (e.g., a second read result or state estimate of the storage element 105) and storage element 106 at state A (e.g., a second read result or state estimate of the storage element 106). In some implementations, the circuitry 150 (e.g., an evaluation unit 404 of FIG. 4) may receive the first and second read results or state estimates for the storage elements 105 and 106 and may be configured to select the first read result or state estimate for the storage element 105 from the first read operation as the read result (state A) based on the storage element 105 having a relatively low TVTD (e.g., based on the indicator 110 for the storage element 105 having the first value), and may select the second read result or state estimate for the storage element 106 from the second read operation as the read result (state A) based on the storage element 106 having a relatively high TVTD (e.g., based on the indicator 110 for the storage element 106 having the second value). In other implementations, the memory 104 may latch results of the first read operation in a first latch at the memory 104, results of the second read operation in a second latch at the memory 104, and values of the indicator 110 in a third latch in the memory 104. The memory 104 may select, bit-by-bit, values from the first latch or from the second latch based on indicator data in the third latch in a manner similar to a look-ahead (LA) operation.

Thus, multiple (e.g., first and second) read operations having different characteristics may be performed to read the storages element 105 and/or 106, and a read result associated with a read operation having a particular characteristic may be selected for each of the storage elements 105 and/or 106 based on the TVTD of the storage element 105 and/or 106 (e.g., based on a value of the indicator 110 for the storage element 105 and/or 106). Selecting the read result of the operation (of the first and second operation) based on the TVTD of the storage element may enable the data storage device 102 to compensate for threshold voltage shifts in a manner that accounts for variations in shifts experienced by storage elements in response to the same temperature cross.

Alternatively or additionally, in some examples, the one or more characteristics of the one or more read operations that may be used to compensate for temperature effects may include one or more voltages (e.g., a “VREAD” voltage) applied to a word line adjacent to a word line being read. Due to cross-coupling effects between storage elements of neighboring word lines, application of a VREAD voltage to a second word line (e.g., the word line 112) adjacent to a first word line (e.g., the word line 111) that includes a storage element to be read may influence a value of a threshold voltage (e.g., a read compare voltage) at which the storage element becomes conductive. Thus, application of a VREAD voltage may be used to adjust a read compare voltage at which a storage element to be read becomes conductive.

For example, to compensate for the shifting and widening (e.g., due to varying threshold voltage temperature dependence of a storage element) of states during a read operation at the memory 104, the data storage device 102 may be configured to perform one or more read operations using one or more VREAD voltages determined based on a TVTD of the storage element. For example, the data storage device 102 may read a state of a storage element of a first word line (e.g., the word line 111) using a first read operation having one or more first VREAD voltages including a first VREAD voltage when the TVTD of the storage element is relatively low (e.g., when a value of the indicator 110 for the storage element being read has the first value). Alternatively or additionally, the data storage device 102 may read the storage element using a second read operation having one or more second VREAD voltages including a second VREAD voltage when the TVTD of the storage element is relatively high (e.g., when a value of the indicator 110 of the storage element being read has the second value).

For example, as described above, the storage element 105 may be programmed at voltage L (associated with state A) at the first temperature, and may be at voltage M at the second temperature. The first read operation having the first VREAD voltage may include applying one or more first read compare voltages including a first read compare voltage associated with state A at the first temperature to the word line 111, and a first VREAD voltage to the word line 112. In this example, the first read compare voltage associated with state A may correspond to a voltage between L and M as described above, and application of the first VREAD voltage to the word line 112 while applying the first read compare voltage may enable the storage element 105 to be correctly read at the second temperature as being programmed to state A.

As another example, as described above, the storage element 106 may be programmed at voltage L (associated with state A) at the first temperature but may be read as having state B in the first read operation in which the first read compare voltage is applied to the word line 110 and the first VREAD voltage is applied to the word line 112. The second read operation having the second VREAD voltage may include applying the one or more first read compare voltages (applied during the first read operation having the first VREAD voltage) including a first read compare voltage associated with state A at the first temperature to the word line 111, and a second VREAD voltage to the word line 112. In this example, and application of the second VREAD voltage to the word line 112 while applying the first read compare voltage may enable the storage element 106 to be correctly read at the second temperature as being programmed to state A.

As described above with reference to the first and second read compare voltages, reading the storage element 105 at the second temperature using the second read operation having the second VREAD voltage may result in the storage element 105 being read as programmed in state E, and reading the storage element 106 at the second temperature using the first read operation having the first VREAD voltage may result in the storage element 106 being read as programmed at state B. Thus, reading one or more of the storage elements by selectively using the first read operation (that employs the first VREAD voltage) or using the second read operation (that employs a second VREAD voltage) based on the TVTD of the storage element (e.g., based on a value of the indicator 110 of the storage element) may enable the data storage device 102 to compensate for threshold voltage shifts in a manner that accounts for variations in shifts experienced by storage elements in response to the same temperature cross.

As described above with reference to reading the word line 111 using multiple read operations having different read compare voltages, in some examples, the data storage device 102 may be configured to read one or more storage elements (e.g., of a word line) by performing multiple read operations (e.g. the first read operation and the second read operation) having the same read compare voltages and different VREAD voltages, and selecting a read result of a particular read operation for a storage element based on the TVTD of the storage element (e.g., based on a value of the indicator 110 of the storage element). For example, the circuitry 150 or circuitry on the memory 104 may perform the first read operation (e.g., may apply the one or more first read compare voltages and the one or more first VREAD voltages) and the second read operation (e.g., may apply the one more first read compare voltages and the one or more second VREAD voltages) and may select a read result of a particular read operation for the storage elements 105 and/or 106 based the TVTD of the storage elements 105 and/or 106 (e.g., based on a value of the indicator 110 of the storage element 105 and/or 106). For example, the circuitry 150 or the circuitry on the memory 104 may select the first read result of the first read operation for the storage element 105 based on the indicator 110 for the storage element 105 having the first value, and may select the second read result of the second read operation for the storage element 106 based on the indicator 110 for the storage element 106 having the second value. In some examples, the read results of the first and second read operations, the indicator value 110 of the storage elements 105 and 106, and temperature information, may be sent to the controller 103. In these examples, the controller 103 may choose which of the first read result or the second read result to use for the storage element 105 and/or 106 based at least in part on the indicator 110 and the temperature cross. Thus, the results of the multiple read operations (each with different VREAD applied to the neighboring word line) may be sent to the controller 103 in addition to the TVTD and the cross-temperature data. Using the TVTD and temperature cross, the controller 103 chooses which of the multiple read results for each cell to be combined into the best representation of the stored data.

Thus, multiple (e.g., first and second) read operations using different characteristics (e.g., different VREAD voltages) may be performed to read the storage elements 105 and/or 106, and a read result associated with a read operation having a particular characteristic (e.g., a particular VREAD voltage) may be selected for each of the storage elements 105 and/or 106 based on the TVTD of the storage elements 105 and/or 106 (e.g., based on a value of the indicator 110 of the storage elements 105 and/or 106). Selecting the read result of the read operation (e.g., the read result of the first or second read operation) based on the TVTD of the storage element may enable the data storage device 102 to compensate for threshold voltage shifts in a manner that accounts for variations in shifts experienced by storage elements in response to the same temperature cross.

Alternatively or additionally, in some examples, the one or more characteristics of the one or more read operations that may be adjusted to compensate for temperature effects may include one or more bit line voltages. For example, the data storage device 102 may read a state of a storage element using a first read operation having a first bit line voltage for the storage element when the TVTD of the storage element is relatively low (e.g., when the indicator 110 for the storage element has the first value). Alternatively or additionally, the data storage device 102 may read the storage element using a second read operation having a second bit line voltage for the storage element when the TVTD of the storage element is relatively high (e.g., when the indicator 110 for the storage element has the second value).

In some examples, the second bit line voltage may be determined relative to the first bit line voltage and may be based at least in part on whether the temperature cross is positive or negative. As an example, the second bit line voltage may be lower than the first bit line voltage when the temperature cross is negative (e.g., a temperature at the time of reading is greater than a temperature at the time of programming). As another example, the second bit line voltage may be greater than the first bit line voltage when the temperature cross is positive (e.g., a temperature at the time of reading is less than a temperature at the time of programming)

For example, the storage element 105 may have a relatively low TVTD (e.g., may have the first value of the indicator 110). In this example, the circuitry 150 may be configured to read the storage element 105 (e.g., to determine the state 160 of the storage element 105) using the first read operation having the first bit line voltage by applying the first read compare voltages (e.g., Vcgr_{EA1}, Vcgr_{AB1}, and/or Vcgr_{BC1}) to the first word line 111 while applying the first bit line voltage to a bit line of the storage element 105 based on the storage element 105 having a relatively low TVTD (e.g., based on the indicator 110 for the storage element having the first value). Reading the storage element 105 at the temperature cross by performing the first read operation having the first bit line voltage (as opposed to reading the storage element 105 at the temperature cross using the second read operation having the second bit line voltage) when the storage element 105 has a relatively low TVTD (e.g., when the indicator 110 for the storage element 105 has the first value) may result in a correct state determination.

As another example, the storage element 106 may have a relatively high TVTD (e.g., the indicator 110 for the storage element 106 may have the second value). In this example, the circuitry 150 may be configured to read the storage element 106 (e.g., to determine the state 160 of the storage element 106) using the second read operation having the second bit line voltage by applying the first read compare voltages (e.g., Vcgr_{EA1}, Vcgr_{AB1}, and/or Vcgr_{BC1}) to the first word line 111 while applying the second bit line voltage to a bit line of the storage element 106 based on the storage element 106 having a relatively high TVTD (e.g., based on the indicator 110 for the storage element 106 having the second value). Reading the storage element 106 at the temperature cross by performing the second read operation having the second bit line voltage (as opposed to reading the storage element 106 at the temperature cross using the first read operation having the first bit line voltage) when the storage element 106 has a relatively high TVTD (e.g., when the indicator 110 for the storage element 106 has the second value) may result in a correct state determination.

In some examples, different bit line voltages may be applied to bit lines of storage elements (based on a TVTD of the storage elements) of a word line during a single read operation. In some examples, the different bit line voltages may be applied in a single read operation using a quick pass write (QPW) bit line bias technique. For example, the memory device 109 may include circuitry configured to selectively bias bit lines at different voltages during a write operation to slow cell programming as cells approach their target level during a QPW programming operation. Such circuitry may be used to selectively bias bit lines at different voltages during a read operation.

For example, the data storage device 102 may be configured to read the storage element 105 and the storage element 106. In this example, the data storage device 102 may read the storage element 105 and the storage element 106 using a single read operation by performing a read operation that includes applying the first bit line voltage to the storage element 105 while applying the second bit line voltage to the storage element 106 based on the respective values of the indicator 110 as described above. The data storage device 102 may sense read values of the storage elements 105 and 106 while applying the first bit line voltage to the storage element 105 and while applying the second bit line voltage to the storage element 106. The data storage device 102 may determine a state of the storage elements 105 and 106 based on the read values sensed while applying the first bit line voltage to the storage element 105 and the second bit line voltage to the storage element 106. Thus, the circuitry 150 may be configured to compensate for threshold voltage shifts by applying different bit line voltages to bit lines of a word line based on the indicator 110 of the storage element during a single read operation.

Alternatively or additionally, in some examples, the one or more characteristics of the one or more read operations that may be adjusted to compensate for temperature effects may include a reliability metric that is used during decoding of data at the ECC engine 164. The reliability metric may be based on hard bit data and soft bit data of the storage element and based on the TVTD of the storage element.

In some examples, the circuitry 150 may be configured to perform the read operation by performing hard and soft bit reads to generate read data (e.g., hard bits and soft bits), and digitally adjusting the read data for each of the storage elements based on the TVTD and/or the indicator 110 of the storage element. The hard and soft bit reads may be performed using different VCGR values to generate hard bits representing read values for the storage elements as determined using coarse VCGR values and soft bits representing a reliability of the hard bits as determined using higher resolution VCGR values.

In some examples, the read data for a storage element may be adjusted (e.g., digitally using digital circuitry) based on a TVTD of the storage element and a temperature cross. For example, an initial read value or state (e.g., corresponding to a sequence of bits including hard bits and soft bits) may be determined for the storage element 105 by sensing (e.g., using a soft bit read) a voltage (e.g., “Vsensed”) of the storage element 105. The circuitry 150 may determine a modified read value or state (e.g., “Vmodified”) by adjusting the sensed voltage Vsensed based on the TVTD of the storage element 105 and the temperature cross. For example, the circuitry 150 may be configured to determine the modified read value or state Vmodified for storage element “i” as in Equation 4, where V(sensed)i corresponds to the sensed read voltage for the storage element i, TVTDᵢ corresponds to the threshold voltage temperature dependence for the storage element i, and TempCross corresponds to a difference in temperature between a time of programming the storage element i and a time of reading the storage element i.

V(modified)ᵢ=V(sensed)ᵢ+TVTDᵢ×TempCross (Eq. 4)

Alternatively or additionally, the read data for a storage element may be adjusted based on a value of the indicator 110 for the storage element and temperature information. For example, the circuitry 150 may be configured to flip a hard bit of read data for the storage element 105 when the hard bit corresponds to a state associated with a low reliability (e.g., as indicated by a soft bit associated with the state) and the storage element 105 has the second value for the indicator 110 (e.g., when the storage element 105 has a relatively high TVTD). In some examples, the hard bit may be flipped based on whether the temperature cross was positive or negative. For example, initial read data for the storage element 105 may correspond to a hard bit value of 1 for an Erase/A region and a soft bit value of 00 (corresponding to a least reliable region). In this example, the circuitry 150 may flip the hard bit value for the storage element 105 from 1 to 0 when the temperature cross is positive (e.g., when the temperature at the time of programming is greater than a temperature at a time of reading the storage element 105). As another example, initial read data for the storage element 105 may correspond to a hard bit value of 0 for an Erase/A region and a soft bit value of 00 (corresponding to a least reliable region). In this example, the circuitry 150 may flip the hard bit value for the storage element 105 from 0 to 1 when the temperature cross is negative (e.g., when the temperature at the time of programming is less than a temperature at a time of reading the storage element 105).

Additionally or alternatively, the circuitry 150 may be configured to determine the state 160 of storage cells by receiving, based on a read operation of a word line that includes the particular storage element, a representation of states of storage elements of the word line, and performing, using error correction coding parameters 408 that are selected based on the indicator 110, an error correction coding operation on the representation of the states of the storage elements to determine the state 160.

To illustrate, the second circuitry 150 may be configured to determine a first soft bit value for the particular storage element by performing at least one soft bit read of the word line. For example, a “hard bit” read of a storage element may include determining the state E, A, B, or C of the storage element by sensing the storage element using the read compare voltages Vcgr_{EA1}, Vcgr_{AB1}, and Vcgr_{BC1}. A “soft bit” read of the storage elements may include sensing the storage elements at voltages other than Vcgr_{EA1}, Vcgr_{AB1}, and Vcgr_{BC1}. As an illustrative, non-limiting example, additional information regarding the state of the storage elements may be obtained by reading the storage elements using read compare voltages Vcgr_{EA1}+Δ, Vcgr_{EA1}−Δ, Vcgr_{AB1}+Δ, Vcgr_{AB1}−Δ, Vcgr_{BC1}+Δ, and Vcgr_{BC1}−Δ, where Δ indicates a voltage offset. Soft bits read from the storage elements may be provided to the ECC engine as the ECC parameters 408 or may be converted to a reliability metric, such as log-likelihood ratios (LLRs) that indicate the value of a storage element (as a sign of the LLR) and a reliability of the value (as a magnitude of the LLR), that may be provided to the ECC engine 164 as the ECC parameters 408.

The second circuitry 150 may be configured to adjust soft bit values based on the indicator 110 to represent a shifted read value, modify a soft bit-to-hard bit conversion based on the indicator 110, or adjust a LLR value based on the indication 110, as illustrative examples. For example, the second circuitry 150 may be configured to determine the one or more ECC parameters 408 based on the first soft bit value for the particular storage element when the indicator 110 for the particular storage element has a first value indicative of a first TVTD for the storage element. The second circuitry 150 may also be configured to determine the one or more ECC parameters 408 based on a second soft bit value for the particular storage element when the indicator 110 for the particular storage element has a second value indicative of a second TVTD for the storage element. The second soft bit value may indicate a lower reliability for the particular storage element. To illustrate, soft bit values received from the memory 104 for a particular storage element may be converted to an LLR value, and the LLR value may be adjusted based on the indicator 110 for the storage element. In some cases, adjusting the LLR value for a storage element may “flip” a hard bit estimate for the storage element.

Additionally or alternatively, in some examples, the one or more memory operations may include one or more program verify operations. In these examples, to compensate for the shifting and widening (e.g., due to varying threshold voltage temperature dependence of a storage element) of states during a program verify operation at the memory 104, the data storage device 102 may be configured to perform one or more program verify operations using one or more characteristics based on a TVTD of the storage element. In some examples, the program verify operations may be performed only when a temperature at the time of programming satisfies a threshold. The one or more characteristics may compensate for an expected voltage shift due to a temperature cross by verifying a programming state of a storage element at a first temperature using a program verify level based on a TVTD of the storage element such that the storage element may be read at a second temperature as having a threshold voltage within a particular voltage range associated with voltage ranges at the second temperature (e.g., after the threshold voltage shifts due to a temperature cross).

For example, distribution plot 202 may illustrate a cell voltage distribution at a first temperature of storage elements as programmed at the first temperature using initial program verify levels (e.g., Verify 1, Verify 2, and/or Verify 3), and distribution plot 206 may illustrate a cell voltage distribution of the storage elements at a second temperature (e.g., higher than the first temperature) when verified using the initial program verify levels. As illustrated in 206, due to the threshold voltage shift experienced by the storage elements due to the temperature cross, reading the storage elements at the second temperature using the first read compare voltage levels VcgrEA1, VcgrAB1, and VcgrBC1 may result in storage elements in the cross hatched portions of the distributions of distribution plot 206 being conductive in response to read compare voltage levels associated with a different state than the state in which the storage element was programmed. The one or more characteristics may compensate for an expected voltage shift due to a temperature cross by verifying a programming state of a storage element at a first temperature using a program verify level (e.g., a higher program verify level than the initial program verify levels) based on a TVTD of the storage element such that the storage element may be read at the second temperature as having a threshold voltage within a particular voltage range associated with voltage ranges at the second temperature (e.g., after the threshold voltage shifts due to a temperature cross).

In some examples, the program verify operations including the one or more characteristics to compensate for the expected voltage shift are only performed when the temperature of programming satisfies one or more thresholds. For example, the program verify operations using the compensation characteristics may only be employed when the programming temperature exceeds a first threshold corresponding to a substantially high temperature and/or when the programming temperature is less than a second threshold corresponding to a substantially low temperature. In these examples, the compensation characteristics may include using program verify levels that compensate for a threshold voltage increase when the programming temperature satisfies the first threshold. Alternatively, the compensation characteristics may include programming verify levels that compensate for a threshold voltage reduction when the programming temperature satisfies the second threshold.

Verifying a programming state of a storage element at a first temperature by performing the first program verify operation having the first characteristic may result in programming the storage element with a different amount of charge than the amount of charge programmed to the storage element when the state is verified at the first temperature by performing the second program verify operation having the second characteristic. To illustrate, verifying a state A for the storage element 105 or the storage element 106 at the first temperature by performing the first program verify operation having the first characteristic may result in the storage element 105 or the storage element 106 being programmed to a threshold voltage level corresponding to (e.g., slightly greater than) Verify 1′ at the first temperature. In contrast, verifying the state A for the storage element 105 or 106 at the first temperature by performing the second program verify operation having the second characteristic may result in the storage element 105 or the storage element 106 having a threshold voltage level corresponding to (e.g., slightly greater than) the second program verify voltage Verify 1″ at the first temperature.

In some examples, the one or more characteristics may include one or more program verify voltages of a program verify operation. For example, to compensate for the shifting and widening of states due to temperature cross, the data storage device 102 may be configured to perform one or more program verify operations having one or more program verify voltages based on a TVTD of a storage element.

For example, the storage element 105 may have a relatively low TVTD. In this example, the data storage device 102 may perform a first program verify operation having a first characteristic corresponding to one or more first program verify voltages including a first program verify voltage when the storage element has a relatively low TVTD (e.g., when the indicator 110 has the first value). As an example, the circuitry 150 may perform the first program verify operation (having the one or more first program verify voltages) on the storage element 105 by applying charge to the storage element 105 until the storage element 105 becomes non-conductive in response to a program verify voltage of the one or more first program verify voltages associated with the state at which the storage element 105 is programmed For example, the one or more first program verify voltages may correspond to Verify 1′, Verify 2′, and/or Verify 3′, as illustrated in FIG. 2, and the state to which the storage element 105 is being programmed at the first temperature may correspond to state A. In this example, a first program verify voltage Verify 1′ may be associated with the state A. Verifying the state A of the storage element 105 using the first program verify voltage Verify 1′ may shift up the threshold voltage level of the storage element 105 such that the storage element 105 becomes conductive to the read compare voltage VcgrAB1 (as opposed to VcgrEA1) at the second temperature. Thus, in this example, the circuitry 150 may perform the first program verify operation (having the one or more first program verify voltages) on the storage element 105 to verify the state A at the first temperature by applying charge to the storage element 105 until the storage element 105 becomes non-conductive in response to application of the first program verify voltage Verify 1′ to the word line 111.

Alternatively or additionally, the data storage device 102 may perform a second program verify operation having a second characteristic corresponding to one or more second program verify voltages including a second program verify voltage when the TVTD of the storage element is relatively high (e.g., when the indicator 110 for the storage element has the second value). For example, the storage element 106 may have a relatively high TVTD. In this example, because the storage element 106 experiences a larger threshold voltage shift due to the temperature cross than the storage element 105, verifying the state A of the storage element 106 having the relatively high TVTD using the first program verify levels (e.g., using verify 1′) may not shift the threshold voltage level of the storage element 106 an amount sufficient to prevent the storage element 106 from being conductive in response to VcgrEA1 at the second temperature. In this example, the data storage device 102 may perform one or more second program verify operations having one or more second program verify voltages (that are different than the first program verify voltages) to the storage element 106 based on the storage element 106 having the relatively high TVTD. To illustrate, the one or more second program verify voltages of the second program verify operation may correspond to Verify 1″, Verify 2″, and/or Verify 3″. Verifying the state A of the storage element 106 using the second program verify voltage Verify 1″ may shift up the threshold voltage level of the storage element 106 an amount such that the storage element 106 is non-conductive when sensed using VcgrEA1 and is conductive when sensed using VcgrAB1 at the second temperature. Thus, in this example, the circuitry 150 may perform the second program verify operation (having the one or more second program verify voltages) on the storage element 106 to verify the state A at the first temperature by applying charge to the storage element 106 until the storage element 106 becomes non-conductive in response to application of the second program verify voltage Verify 1″ to the word line 111.

In some examples, the one or more characteristics of the program verify operations may include one or more VREAD voltages, in a similar manner as described for read operations. For example, to compensate for the shifting a widening of states due to temperature cross, the data storage device 102 may be configured to perform one or more program verify operations using one or more VREAD voltages based on a TVTD of a storage element.

In some examples in which the one or more characteristics include different program verify voltages and/or VREAD voltages, the data storage device 102 may employ ramp sensing. For example, a read compare voltage may be “ramped” (e.g., continually or step-wise increased) and each storage element's transition from non-conductive to conductive may be used to identify a programming state of the storage element. Using ramp sensing may increase a speed of program verify operations that are use different program verify voltages (e.g., Verify 1′ or Verify 1″) for different storage element as compared to implementations that do not use ramp sensing.

In some examples, the one or more characteristics of the program verify operations may include one or more bit line voltages, in a similar manner as described for read operations. For example, to compensate for the shifting a widening of states due to temperature cross, the data storage device 102 may be configured to perform one or more program verify operations having one or more bit line voltages based on a TVTD of a storage element.

Thus, selectively performing the first program verify operation having the first characteristic (e.g., the one or more first program verify voltages, the one or more first VREAD voltages, and/or the one or more first bit line voltages) or the second program verify operation having the second characteristic (e.g., the one or more second program verify voltages, the one or more second VREAD voltages, and/or the one or more second bit line voltages) may enable storage elements that experience a different amount of threshold voltage level shift due to a temperature cross to be read at the temperature cross using a single set of read compare voltages.

In some examples, the one or more memory operations may include one or more cell voltage distribution (CVD) determination operations. In these examples, to compensate for the shifting and widening (e.g., due to varying threshold voltage temperature dependence of storage elements) of states due to temperature cross, the circuitry 150 may be configured to perform one or more CVD determination operations having one or more characteristics based on a TVTD of the storage elements. The one or more CVD determination operations may include one or more distribution read operations, and the one or more characteristics of the CVD determination operations may include a read reference voltage or a bit line voltage. During a distribution read operation, threshold voltages of storage elements may be sensed by stepping through read reference voltages associated with voltage bins. The storage elements may be assigned to voltage bins based on the voltage bin associated with a read reference voltage in response to which the storage element becomes conductive. Due to temperature cross, storage elements with a relatively high TVTD may experience a threshold voltage shift that causes the higher-TVTD storage elements to be sensed at a read reference voltage corresponding to a different voltage bin than the voltage bin at which the storage elements would have been sensed at the programming temperature.

In some examples, the one or more characteristics of the CVD determination operations may include read reference voltages. In these examples, multiple distribution reads may be performed using different voltage grids (e.g., different sets of read reference voltages) based on the TVTD of the storage element. For example, a first distribution read operation having one or more read reference voltages may be performed to determine voltage bin information. Each value of the indicator 110 may be associated with a particular voltage grid (e.g., a particular set of read reference voltages), and a voltage bin for a storage element may be determined based on a read reference value from a distribution read operation that employs a voltage grid associated with the value of the indicator 110 of the storage element. For example, a first distribution read operation may use a first voltage grid (e.g., may apply first read reference voltages) associated with a first value of the indicator 110 indicating lower-TVTD. A second distribution read may use a second voltage grid (e.g., may apply second read references voltages) associated with a second value of the indicator 110 indicating higher-TVTD and may include second read reference voltages. In this example, first read reference values (results) from the first distribution read may be used to determine a voltage bin for lower-TVTD storage elements, and second read reference values (results) from the second distribution read may be used to determine a voltage bin for higher-TVTD storage elements.

Thus, the circuitry 150 may be configured to compensate for voltage bin errors resulting from threshold voltage shifts due to temperature cross by performing multiple distribution reads using different voltage grids and selecting a bin for a storage element based on a read reference value of a distribution read associated with the indicator 110. Determining the voltage bin for the storage element using a voltage grid associated with a value of the indicator of the storage element may result in assigning correct voltage bins to storage elements despite differences in threshold voltage shift of the storage elements in response to a same temperature cross.

Alternatively or additionally, the circuitry 150 may be configured to compensate by applying a particular bit line voltage to bit lines of storage elements during a distribution read operation (e.g., a single distribution read operation) based on the value of the indicator 110. For example, a first bit line voltage (e.g., a default bit line voltage) may be applied, during a distribution read operation, to storage elements of the word line 111 that have a first value of the indicator 110 (e.g., a value of the indicator 110 indicative of storage elements that are not prone to large voltage shifts in response to a temperature cross). A second bit line voltage may be applied during the distribution read operation to storage elements that have a second value of the indicator 110 (e.g., indicative of being prone to large voltage shifts in response to a temperature cross).

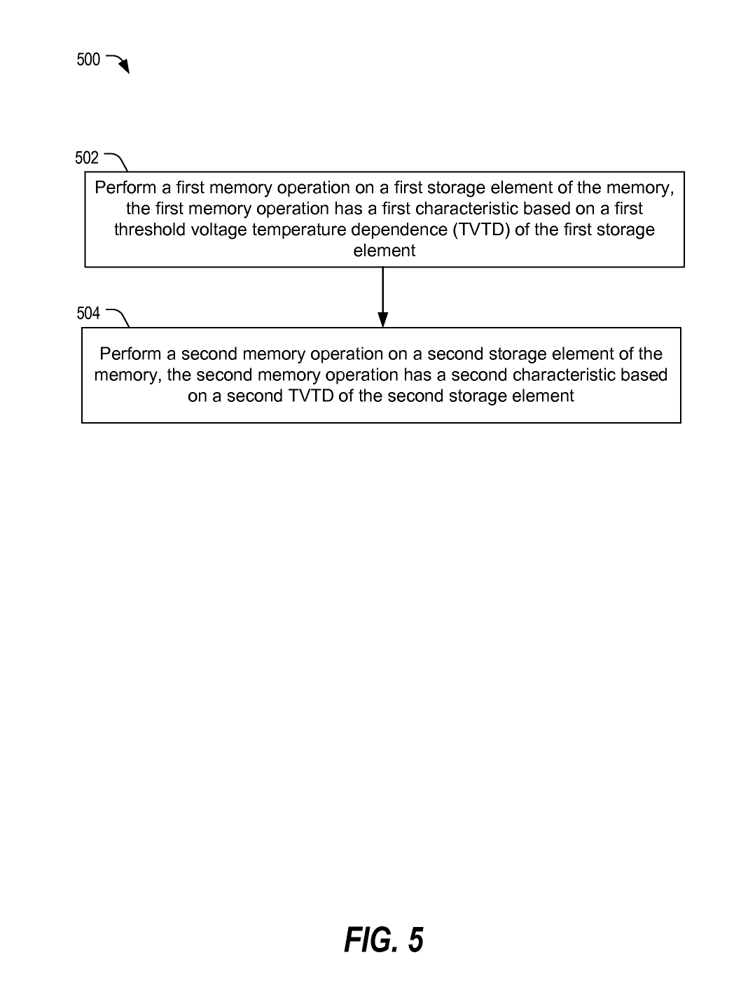

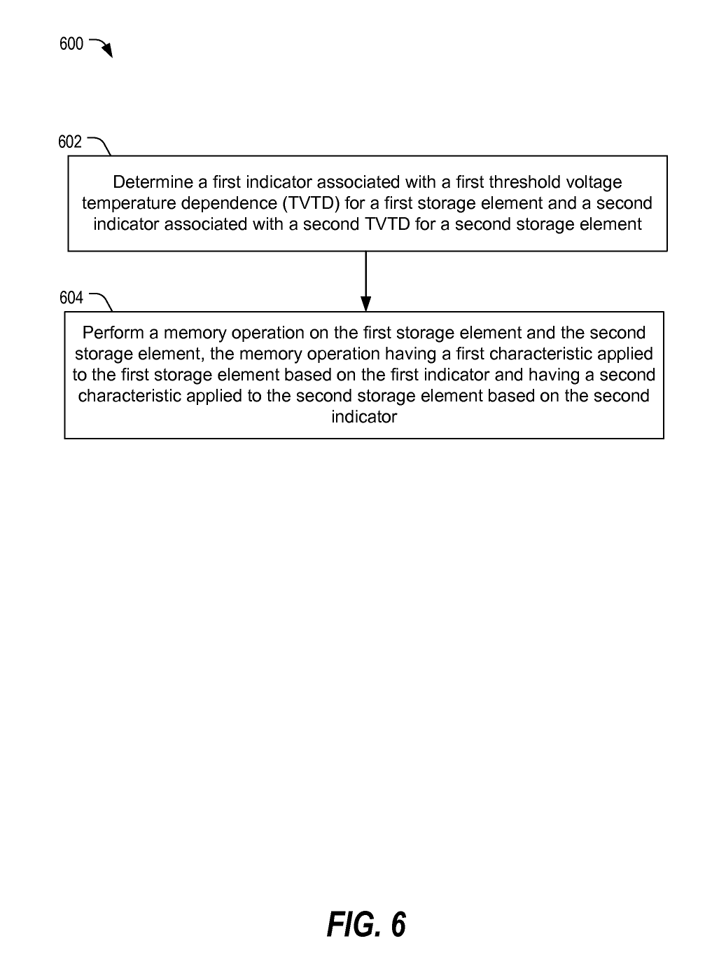

Referring to FIG. 5, a particular embodiment of a method 500 is depicted. The method 500 may be performed in a data storage device, such as the data storage device 102 of FIG. 1.

The method 500 of FIG. 5 may include performing, at 502, a first memory operation on a first storage element of the memory 104. The first memory operation may have a first characteristic based on a first threshold voltage temperature dependence (TVTD) of the first storage element.

For example, the first storage element may correspond to the first storage element 105 of FIG. 1, the first memory operation may include a first read operation, and the first characteristic may correspond to one or more read compare voltages, one or more VREAD values, one or more bit line voltages, or any combination thereof, as described above. For example, performing the first memory operation may include performing the first read operation having the one or more first read compare voltages, performing the first read operation having the first VREAD voltage, and/or performing the first read operation having the first bit line voltage to read the storage element 105 at the second temperature when the storage element 105 has a relatively low TVTD as described above (e.g., when the indicator 110 for the storage element 105 has the first value described above).

As another example, the first storage element may correspond to the first storage element 105 of FIG. 1, the first memory operation may include a first program verify operation, and the first characteristic may correspond to one or more program verify voltages, one or more VREAD voltages, one or more bit line voltages, or any combination thereof, as described above. For example, performing the first memory operation may include performing the first program verify operation having the one or more first program verify voltages, performing the first program verify operation having the first VREAD voltage, and/or performing the first program verify operation having the first bit line voltage to program the storage element 105 at the first temperature when the storage element 105 has a relatively low TVTD as described above (e.g., when the indicator 110 for the storage element 105 has the first value described above).

The method 500 of FIG. 5 may include performing, at 504, a second memory operation on a second storage element of the memory 104, and the second memory operation may have a second characteristic based on a second TVTD of the second storage element, wherein the first TVTD is different than the second TVTD.

For example, the second storage element may correspond to the second storage element 106 of FIG. 1, the second memory operation may include a second read operation, and the second characteristic may correspond to one or more read compare voltages, one or more VREAD values, one or more bit line voltages, or any combination thereof, as described above. For example, performing the second memory operation may include performing the second read operation having the one or more second read compare voltages, performing the second read operation having the second VREAD voltage, and/or performing the second read operation having the second bit line voltage to read the storage element 106 at the second temperature when the storage element 106 has a relatively low TVTD as described above (e.g., when the indicator 110 for the storage element 106 has the second value described above).

As another example, the second storage element may correspond to the second storage element 106 of FIG. 1, the second memory operation may include a second program verify operation, and the second characteristic may correspond to one or more program verify voltages, one or more VREAD voltages, one or more bit line voltages, or any combination thereof, as described above. For example, performing the second memory operation may include performing the second program verify operation having the one or more second program verify voltages, performing the second program verify operation having the second VREAD voltage, and/or performing the second program verify operation having the second bit line voltage to program the storage element 106 at the first temperature when the storage element 106 has a relatively low TVTD as described above (e.g., when the indicator 110 for the storage element 106 has the second value described above).

Referring to FIG. 6, a particular embodiment of a method 600 is depicted. The method 600 may be performed in a data storage device, such as the data storage device 102 of FIG. 1.

The method 600 of FIG. 6 may include determining, at 602, a first indicator for a first storage element and a second indicator for a second storage element. For example, the first storage element may correspond to the storage element 105, the second storage element may correspond to the storage element 106, and the first and second indicator may correspond to values of the indicator 110 determined as described above with reference to FIGS. 1 and 3. For example, the first indicator may be determined based on a DIBL of the storage element 105, and the second indicator may be determined based on a DIBL of the storage element 106, as described above.

The method 600 of FIG. 6 may include performing, at 604, performing a memory operation on the first storage element and the second storage element. The memory operation has a first characteristic applied to the first storage element based on the first indicator and has a second characteristic applied to the second storage element based on the second indicator. In some examples, the one or more characteristics may correspond to a bit line voltage, a program verify voltage, or a LLR adjustment amount. Selectively using different characteristics, such as different bit line voltages, may compensate for threshold voltage shifts experienced as a result of temperature cross as described above. Thus, the method 600 of FIG. 6 may include performing a single memory operation using different characteristics based on a TVTD (or indicator) of a storage element to compensate for threshold voltage shifts due to temperature cross.

Although various components depicted herein are illustrated as block components and described in general terms, such components may include one or more microprocessors, state machines, or other circuits configured to enable the first circuitry 140 of FIG. 1 to determine TVTD data and to generate the indicator 110 and to enable the second circuitry 150 to determine storage element states at least partially based on the indicator 110. For example, the first circuitry 140 and the second circuitry 150 may represent physical components, such as hardware controllers, state machines, logic circuits, or other structures, to enable the first circuitry 140 and the second circuitry 150 of FIG. 1 to generate values of the indicator 110 for each storage element of a memory operation and to use the respective values of the indicator 110 to determine a state of each storage element.

The first circuitry 140 and/or the second circuitry 150 may be implemented using a microprocessor or microcontroller programmed to generate values of the indicator 110 for each storage element of a memory operation and to use the respective values of the indicator 110 to determine a state of each storage element, such as by comparing a stored temperature indicator for the storage elements to a temperature sensor output and generating the indicator values in response to a temperature difference exceeding a threshold. Generating the indicator values may be performed by reading values of the storage elements using a first bit line voltage to generate first results, reading values of the storage elements using a second bit line voltage to generate second results, and selecting, for each storage element, an indicator value based in whether a difference between the first result and the second result for the storage element exceeds a threshold. Using the indicator may include performing a memory operation to get first storage element state estimates using a first characteristic (e.g., a first set of read compare values, a first bit line value, a first read voltage), repeating the memory operation to get second storage element state estimates using a second characteristic (e.g., a second set of read compare values, a second bit line value, a second read voltage), and selecting, for each storage element, the first state estimate or the second state estimate for the storage element based on the value of the indicator for the storage element. In a particular embodiment, the controller 103 includes a processor executing instructions that are stored at the non-volatile memory 104. Alternatively, or in addition, executable instructions that are executed by the processor may be stored at a separate memory location that is not part of the non-volatile memory 104, such as at a read-only memory (ROM).

With reference to FIG. 1, the data storage device 102 may be attached to or embedded within one or more accessing devices, such as within a housing of the accessing device 130. For example, the data storage device 102 may be embedded within the accessing device 130 in accordance with a Joint Electron Devices Engineering Council (JEDEC) Solid State Technology Association Universal Flash Storage (UFS) configuration. To further illustrate, the data storage device 102 may be integrated within an apparatus, such as a mobile telephone, a computer (e.g., a laptop, a tablet, or a notebook computer), a music player, a video player, a gaming device or console, an electronic book reader, a personal digital assistant (PDA), a portable navigation device, or other device that uses non-volatile memory. However, in other implementations, the data storage device 102 may be implemented in a portable device configured to be selectively coupled to one or more external accessing devices. For example, the data storage device 102 may be removable from the accessing device 130 (i.e., “removably” coupled to the accessing device 130). As an example, the data storage device 102 may be removably coupled to the accessing device 130 in accordance with a removable universal serial bus (USB) configuration. In still other implementations, the data storage device 102 may be a component (e.g., a solid-state drive (SSD)) of a network accessible data storage system, such as an enterprise data system, a network-attached storage system, a cloud data storage system, etc.

The memory 104 may include a resistive random access memory (ReRAM), a three-dimensional (3D) memory, a flash memory (e.g., a NAND memory, a NOR memory, a single-level cell (SLC) flash memory, a multi-level cell (MLC) flash memory, a divided bit-line NOR (DINOR) memory, an AND memory, a high capacitive coupling ratio (HiCR) device, an asymmetrical contactless transistor (ACT) device, or another flash memory), an erasable programmable read-only memory (EPROM), an electrically-erasable programmable read-only memory (EEPROM), a read-only memory (ROM), a one-time programmable memory (OTP), or a combination thereof. Alternatively, or in addition, the memory 104 may include another type of memory. In some implementations, one or more of the memory 104 may include a semiconductor memory device.

Semiconductor memory devices include volatile memory devices, such as dynamic random access memory (“DRAM”) or static random access memory (“SRAM”) devices, non-volatile memory devices, such as magnetoresistive random access memory (“MRAM”), resistive random access memory (“ReRAM”), electrically erasable programmable read only memory (“EEPROM”), flash memory (which can also be considered a subset of EEPROM), ferroelectric random access memory (“FRAM”), and other semiconductor elements capable of storing information. Each type of memory device may have different configurations. For example, flash memory devices may be configured in a NAND or a NOR configuration.

The memory devices can be formed from passive and/or active elements, in any combinations. By way of non-limiting example, passive semiconductor memory elements include ReRAM device elements, which in some implementations include a resistivity switching storage element, such as an anti-fuse, phase change material, etc., and optionally a steering element, such as a diode, etc. Further by way of non-limiting example, active semiconductor memory elements include EEPROM and flash memory device elements, which in some implementations include elements containing a charge storage region, such as a floating gate, conductive nanoparticles, or a charge storage dielectric material.

Multiple memory elements may be configured so that they are connected in series or so that each element is individually accessible. By way of non-limiting example, flash memory devices in a NAND configuration (NAND memory) typically contain memory elements connected in series. A NAND memory array may be configured so that the array is composed of multiple strings of memory in which a string is composed of multiple memory elements sharing a single bit line and accessed as a group. Alternatively, memory elements may be configured so that each element is individually accessible, e.g., a NOR memory array. NAND and NOR memory configurations are exemplary, and memory elements may be otherwise configured.

The semiconductor memory elements located within and/or over a substrate may be arranged in two or three dimensions, such as a two dimensional memory structure or a three dimensional memory structure. In a two dimensional memory structure, the semiconductor memory elements are arranged in a single plane or a single memory device level. Typically, in a two dimensional memory structure, memory elements are arranged in a plane (e.g., in an x-z direction plane) which extends substantially parallel to a major surface of a substrate that supports the memory elements. The substrate may be a wafer over or in which the layer of the memory elements are formed or it may be a carrier substrate which is attached to the memory elements after they are formed. As a non-limiting example, the substrate may include a semiconductor such as silicon.

The memory elements may be arranged in the single memory device level in an ordered array, such as in a plurality of rows and/or columns. However, the memory elements may be arrayed in non-regular or non-orthogonal configurations. The memory elements may each have two or more electrodes or contact lines, such as bit lines and word lines.

A three dimensional memory array is arranged so that memory elements occupy multiple planes or multiple memory device levels, thereby forming a structure in three dimensions (i.e., in the x, y and z directions, where the y direction is substantially perpendicular and the x and z directions are substantially parallel to the major surface of the substrate). As a non-limiting example, a three dimensional memory structure may be vertically arranged as a stack of multiple two dimensional memory device levels. As another non-limiting example, a three dimensional memory array may be arranged as multiple vertical columns (e.g., columns extending substantially perpendicular to the major surface of the substrate, i.e., in the y direction) with each column having multiple memory elements in each column. The columns may be arranged in a two dimensional configuration, e.g., in an x-z plane, resulting in a three dimensional arrangement of memory elements with elements on multiple vertically stacked memory planes. Other configurations of memory elements in three dimensions can also constitute a three dimensional memory array.

By way of a non-limiting example, in a three dimensional NAND memory array, the memory elements may be coupled together to form a NAND string within a single horizontal (e.g., x-z) memory device levels. Alternatively, the memory elements may be coupled together to form a vertical NAND string that traverses across multiple horizontal memory device levels. Other three dimensional configurations can be envisioned wherein some NAND strings contain memory elements in a single memory level while other strings contain memory elements which span through multiple memory levels. Three dimensional memory arrays may also be designed in a NOR configuration and in a ReRAM configuration.

Typically, in a monolithic three dimensional memory array, one or more memory device levels are formed above a single substrate. Optionally, the monolithic three dimensional memory array may also have one or more memory layers at least partially within the single substrate. As a non-limiting example, the substrate may include a semiconductor material such as silicon. In a monolithic three dimensional array, the layers constituting each memory device level of the array are typically formed on the layers of the underlying memory device levels of the array. However, layers of adjacent memory device levels of a monolithic three dimensional memory array may be shared or have intervening layers between memory device levels.

Alternatively, two dimensional arrays may be formed separately and then packaged together to form a non-monolithic memory device having multiple layers of memory. For example, non-monolithic stacked memories can be constructed by forming memory levels on separate substrates and then stacking the memory levels atop each other. The substrates may be thinned or removed from the memory device levels before stacking, but as the memory device levels are initially formed over separate substrates, the resulting memory arrays are not monolithic three dimensional memory arrays. Further, multiple two dimensional memory arrays or three dimensional memory arrays (monolithic or non-monolithic) may be formed on separate chips and then packaged together to form a stacked-chip memory device.

Associated circuitry is typically used for operation of the memory elements and for communication with the memory elements. As non-limiting examples, memory devices may have circuitry used for controlling and driving memory elements to accomplish functions such as programming and reading. This associated circuitry may be on the same substrate as the memory elements and/or on a separate substrate. For example, a controller for memory read-write operations may be located on a separate controller chip and/or on the same substrate as the memory elements.

One of skill in the art will recognize that this disclosure is not limited to the two dimensional and three dimensional illustrative structures described but cover all relevant memory structures within the scope of the disclosure as described herein and as understood by one of skill in the art. The illustrations of the examples described herein are intended to provide a general understanding of the various aspects of the disclosure. Other implementations may be utilized and derived from the disclosure, such that structural and logical substitutions and changes may be made without departing from the scope of the disclosure. This disclosure is intended to cover any and all subsequent adaptations or variations of various implementations. Those of skill in the art will recognize that such modifications are within the scope of the present disclosure.

The above-disclosed subject matter is to be considered illustrative, and not restrictive, and the appended claims are intended to cover all such modifications, enhancements, and other implementations, that fall within the scope of the present disclosure. Thus, to the maximum extent allowed by law, the scope of the present disclosure is to be determined by the broadest permissible interpretation of the following claims and their equivalents, and shall not be restricted or limited by the foregoing detailed description.

What is claimed is:

1. A data storage device comprising:
a memory including multiple storage elements; and
circuitry configured to determine, for a particular storage element of the multiple storage elements, an indicator associated with a threshold voltage temperature dependence (TVTD) of the particular storage element.

2. The data storage device of claim 1, wherein the circuitry is configured to determine the indicator during a read operation associated with a word line that includes the particular storage element.

3. The data storage device of claim 1, wherein the circuitry is configured to determine the indicator responsive to a determination that a first temperature of at least a portion of the memory at a time of programming the particular storage element satisfies a threshold.

4. The data storage device of claim 1, wherein the circuitry is configured to determine a temperature difference between a first temperature at a first time of programming the particular storage element and a second temperature at a second time of reading the particular storage element, and wherein the circuitry is configured to determine the indicator in response to determining that the temperature difference is greater than or equal to a threshold.

5. The data storage device of claim 1, wherein the circuitry is configured to determine the indicator based on a determined drain induced barrier lowering value associated with the particular storage element.

6. The data storage device of claim 1, wherein the circuitry is configured to determine the indicator by:
causing a first bit line voltage to be applied to a first bit line associated with the particular storage element;
while the first bit line voltage is applied, performing a first read operation of a word line that includes the particular storage element to determine a first threshold voltage result for the particular storage element;
causing a second bit line voltage to be applied to the first bit line;
while the second bit line voltage is applied, performing a second read operation of the word line to determine a second threshold voltage result for the particular storage element;
determining a threshold voltage difference associated with the particular storage element based on the first threshold voltage result and the second threshold voltage result; and
determining the indicator based on the threshold voltage difference.

7. The data storage device of claim 6, wherein the indicator is determined to correspond to a first logical value in response to the threshold voltage difference of the particular storage element satisfying a threshold and is determined to correspond to a second logical value in response to the threshold voltage difference of the particular storage element failing to satisfy the threshold.

8. The data storage device of claim 1, further comprising second circuitry that includes an error correction coding (ECC) engine, and wherein the second circuitry is configured to determine a state of the particular storage element based on the indicator by:
receiving, based on a read operation at a word line that includes the particular storage element, a representation of states of storage elements of the word line; and
performing, using one or more ECC parameters determined based at least in part on the indicator, an ECC operation on the representation of the states of the storage elements to determine the state.

9. The data storage device of claim 8, wherein the one or more ECC parameters include a log likelihood ratio (LLR).

10. The data storage device of claim 8, wherein the one or more ECC parameters include a reliability metric determined further based on hard bit data and soft bit data of the particular storage element.

11. A method comprising:
at a data storage device comprising a memory, performing:
a first memory operation on a first storage element of the memory, the first memory operation having a first characteristic based on a first threshold voltage temperature dependence (TVTD) of the first storage element; and
a second memory operation on a second storage element of the memory, the second memory operation having a second characteristic based on a second TVTD of the second storage element, the second TVTD is different than the first TVTD.

12. The method of claim 11, wherein the first memory operation corresponds to a first read operation and the second memory operation corresponds to a second read operation, wherein the first characteristic is different than the second characteristic, and wherein the first read operation and the second read operation are performed at a substantially similar temperature of the memory.

13. The method of claim 11, wherein the first characteristic comprises one or more first read compare voltages and the second characteristic comprises one or more second read compare voltages.

14. The method of claim 11, wherein the first characteristic comprises a first bit line voltage and the second characteristic comprises a second bit line voltage.

15. The method of claim 11, wherein the first characteristic comprises a first word line voltage applied during the first memory operation to a second word line adjacent to a first word line that includes the first and second storage elements, and the second characteristic comprises a second word line voltage applied to the second word line during the second memory operation.

16. The method of claim 11, wherein the first memory operation includes an error correcting code (ECC) operation and the first characteristic comprises a reliability metric determined based on hard bit data and soft bit data of the first storage element and based on the first TVTD.

17. The method of claim 16, further comprising determining the reliability metric by adjusting a first reliability metric of the first storage element based on the first TVTD.

18. The method of claim 11, wherein performing the first memory operation having the first characteristic based on the first TVTD and performing the second memory operation having the second characteristic based on the second TVTD includes:
performing a first read operation to determine a first state estimate associated with the first storage element and a first state estimate associated with the second storage element;
performing a second read operation to determine a second state estimate associated with the first storage element and a second state estimate associated with the second storage element;
selecting, as a state for the first storage element, the first state estimate associated with the first storage element or the second state estimate associated with the first storage element based on the first TVTD; and
selecting, as a state for the second storage element, the first state estimate associated with the second storage element or the second state estimate associated with the second storage element based on the second TVTD.

19. The method of claim 18, wherein the first state estimate associated with the first storage element is selected as the state for the first storage element and the second state estimate associated with the second storage element is selected as the state for the second storage element if the first TVTD is less than the second TVTD.

20. The method of claim 11, further comprising determining a first indicator associated with the first TVTD by measuring a drain induced barrier lowering value associated with the first storage element.

21. The method of claim 20, wherein the first indicator is determined responsive to determining that a difference between a first temperature at a first time of programming the first storage element and a second temperature at a second time of performing the first memory operation is greater than or equal to a threshold.

22. The method of claim 11, further comprising determining a first indicator associated with the first TVTD and a second indicator associated with the second TVTD by:
applying a first bit line voltage to a first bit line associated with the first storage element and applying a second bit line voltage to a second bit line associated with the second storage element;
while the first bit line voltage and the second bit line voltage are applied, performing a first read operation of a word line coupled to the first storage elements and to the second storage element to determine a first threshold result of the first read operation for the first storage element and a second threshold result of the first read operation for the second storage element;
applying a third bit line voltage to the first bit line and applying a fourth bit line voltage to the second bit line;
while the third bit line voltage and the fourth bit line voltage are applied, performing a second read operation of the word line to determine a third threshold result of the second read operation for the first storage element and a fourth threshold result of the second read operation for the second storage element;
determining a first threshold voltage difference associated with the first storage element based on the first threshold result and the third threshold result, wherein the first indicator is determined based on the first threshold voltage difference; and
determining a second threshold voltage difference associated with the second storage element based on the second threshold result and the fourth threshold result, wherein the second indicator is determined based on the second threshold voltage difference.

23. A data storage device comprising:
a memory including multiple storage elements; and
circuitry configured to determine for a particular storage element of the multiple storage elements:
a drain induced barrier lowering (DIBL) value associated with the particular storage element; and
a state of the storage element based on a memory operation and based on the DIBL value.

24. The data storage device of claim 23, wherein the circuitry is configured to determine the DIBL value during a read operation associated with a word line that includes the particular storage element.

25. The data storage device of claim 23, wherein the circuitry is configured to determine the state of the particular storage element based on the DIBL value by selectively applying, based on the DIBL value, a first bit line voltage to a bit line associated with the particular storage element during a read operation.

26. The data storage device of claim 25, wherein the first bit line voltage is selectively applied to the bit line of the particular storage element by applying the first bit line voltage to the bit line if the DIBL value is indicative of a high threshold voltage temperature dependence (TVTD) for the particular storage element and applying a second bit line voltage to the bit line if the DIBL value is indicative of a low TVTD for the particular storage element.

27. The data storage device of claim 23, wherein the circuitry is configured to determine the state of the particular storage element based on the DIBL value during a read operation of a word line including the particular storage element by selectively applying, based on the DIBL value, one or more first read compare voltages to the word line.

28. The data storage device of claim 27, wherein the one or more first read compare voltages are selectively applied to the word line based on the DIBL value by applying the one or more first read compare voltages to the word line if the DIBL value is indicative of a high threshold voltage temperature dependence (TVTD) for the particular storage element and applying one or more second read compare voltages to the word line if the DIBL value is indicative of a low TVTD for the particular storage element.

29. The data storage device of claim 23, wherein the circuitry is configured to determine the state of the particular storage element based on the DIBL value during a read operation by:
applying multiple read voltages to determine multiple state estimates associated with the particular storage element; and
selecting, as the state, a particular state estimate of the multiple state estimates based on the DIBL value.

30. A data storage device comprising:
a memory including multiple storage elements; and
circuitry configured to:
perform a first memory operation on a first storage element of the memory, the first memory operation having a first characteristic based on a first threshold voltage temperature dependence (TVTD) of the first storage element; and
perform a second memory operation on a second storage element of the memory, the second memory operation having a second characteristic based on a second TVTD of the second storage element, the second TVTD is different than the first TVTD.

31. The data storage device of claim 30, wherein the first memory operation corresponds to a first read operation and the second memory operation corresponds to a second read operation, wherein the first characteristic is different than the second characteristic, and wherein the first read operation and the second read operation are performed at a substantially similar temperature of the memory.

32. The data storage device of claim 30, wherein the first characteristic comprises one or more first read compare voltages and the second characteristic comprises one or more second read compare voltages that are different than the one or more first read compare voltages.

33. The data storage device of claim 30, wherein the first characteristic comprises a first bit line voltage and the second characteristic comprises a second bit line voltage that is different than the first bit line voltage.

34. The data storage device of claim 30, wherein the first characteristic comprises a first word line voltage applied during the first memory operation to a second word line adjacent to a first word line that includes the first and second storage elements, and the second characteristic comprises a second word line voltage applied to the second word line during the second memory operation.

35. The data storage device of claim 30, wherein the first memory operation includes an error correcting code (ECC) operation and the first characteristic comprises a reliability metric determined based on hard bit data and soft bit data of the first storage element and based on the first TVTD.

36. The data storage device of claim 35, wherein the reliability metric is determined by adjusting a first reliability metric of the first storage element based on the first TVTD.

37. The data storage device of claim 30, wherein the circuitry is further configured to perform the first memory operation and the second memory operation by:
performing a first read operation during application of a first VREAD voltage to a second word line adjacent to a first word line that includes the first storage element and the second storage element to determine a first state estimate associated with the first storage element and a first state estimate associated with the second storage element;
performing a second read operation during application of a second VREAD voltage to the second word line to determine a second state estimate associated with the first storage element and a second state estimate associated with the second storage element;
selecting, as a state for the first storage element, the first state estimate associated with the first storage element or the second state estimate associated with the first storage element based on the first TVTD; and
selecting, as a state for the second storage element, the first state estimate associated with the second storage element or the second state estimate associated with the second storage element based on the second TVTD.

38. The data storage device of claim 37, wherein the circuitry is further configured to select the state for the first storage element and the state for the second storage element based on a temperature difference between a first temperature at a time of programming the first word line and a second temperature at a time of performing the first read operation and the second read operation.

39. A method comprising:
at a data storage device comprising a memory, performing:
determining a first indicator associated with a first threshold voltage temperature dependence (TVTD) of a first storage element of the memory and a second indicator associated with a second TVTD of the memory; and
performing a memory operation on the first storage element and the second storage element, the memory operation having a first characteristic applied to the first storage element based on the first indicator and having a second characteristic applied to the second storage element based on the second indicator.

40. The method of claim 39, wherein the first characteristic comprises a first bit line voltage and the second characteristic comprises a second bit line voltage.

41. The method of claim 39, wherein the memory operation includes an error correcting code (ECC) operation and the first characteristic comprises a reliability metric determined based on hard bit data and soft bit data of the first storage element and based on the first indicator.

42. The method of claim 39, wherein the first characteristic comprises a first program verify voltage and the second characteristic comprises a second program verify voltage.
